(19) United States
(12) Patent Application Publication
(10) Pub. No.: US 2008/0048293 A1
(43) Pub. Date: Feb. 28, 2008

(54) SEMICONDUCTOR DEVICE HAVING HEATING STRUCTURE AND METHOD OF FORMING THE SAME

(75) Inventor: Hideki Horii, Seoul (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/842,183

(22) Filed: Aug. 21, 2007

(30) Foreign Application Priority Data
Aug. 22, 2006 (KR) 2006-79552
Sep. 11, 2006 (KR) 2006-87667

(51) Int. Cl. H01L 47/00; H01L 21/8234; H01L 29/00; H01L 21/20

(52) U.S. Cl. 257/536; 438/382; 257/E27.047

(57) ABSTRACT

A semiconductor device includes a lower electrode including a bottom wall portion and a sidewall portion extending upwardly from the bottom wall portion, and an insulating layer located over a top edge surface of the sidewall portion of the lower electrode. The insulating layer includes a contact window which partially exposes the top edge surface of the sidewall portion of the lower electrode. The device further includes a heated pattern which contacts the partially exposed top edge surface of the sidewall portion of the lower electrode through the contact window of the insulating layer.

### CROSS-REFERENCE TO RELATED APPLICATIONS

A claims priority under 35 U.S.C. § 119 is made to Korean Patent Application Nos. 10-2006-79552, filed Aug. 22, 2006, and 10-2006-87667, filed Sep. 11, 2006, the entire contents of which are hereby incorporated by reference.

### BACKGROUND OF THE INVENTION

The present invention generally relates to a semiconductor device and a method of forming the same, and more particularly, to a semiconductor device having a heating structure and a method of forming the same.

With the rapid development of electronics industries such as mobile telecommunication and computer industries, a demand has arisen for semiconductor memory devices characterized by high cell integration, fast read/write operational speed, non-volatility storage capabilities, and low operational voltages. Conventional memories, however, such as static random access memories (SRAM), dynamic random access memories (DRAM), and flash memories, typically fall short in one or more of these operational areas.

For example, since the unit cell of a DRAM includes one capacitor and one transistor (that controls the capacitor), a DRAM is characterized by a relatively large unit cell area (e.g., when compared to a NAND flash memory). Additionally, a DRAM is a volatile memory since the capacitor of a DRAM cell must be regularly refreshed to maintain its charge. Further, while an SRAM has a fast operational speed, it is also volatile memory device. Moreover, since the unit cell of the SRAM includes six transistors, and thus suffers the drawback of a relatively large unit cell area. In the meantime, a flash memory is a non-volatile memory device, and provides the highest degree of integration among conventional memory devices (particularly in the case of a NAND flash memory device). However, the flash memory suffers the drawback of a relatively slow operational speed.

In an effort to overcome the inherent drawbacks of conventional memories, a phase random access memory (PRAM) has recently been subject of study as a next generation type of memory. For example, since PRAM is capable of performing information changes of more than 10¹³, exhibits excellent durability, and is capable of high operational speeds (e.g., 30 ns).

The information stored in the memory cell of PRAM can be read by sensing the change of electrical resistance thereof, which depends on crystal state in a phase change layer. The crystal state of the phase change layer depends on a heating temperature and heating time of the phase change layer during a write operation. In a PRAM, a method of adjusting a current flowing in the phase change layer and Joule's heat caused by the current is utilized to program the phase change layer to a desirable crystal state. The Joule's heat Q produced from a resistive heater having a resistance R can be expressed by Equation 1 below.

Q=I²*R*t Equation 1

In Equation 1, the current passing through the resistive heater is I, and the application time of the current is T. The resistance R is a fixed parameter, which depends a material of and/or manufacturing processes used to fabricate the resistive heater, while the time t and the current I are externally controllable parameters. In order to minimize power consumption, it desirable to utilize a resistive heater having a high resistance R.

FIG. 1A is a plan view of a conventional PRAM memory cell, and FIG. 1B is a sectional view taken along Line I-I′ of FIG. 1A. FIG. 1C is a diagram illustrating resistive components of a conventional PRAM.

Referring to FIGS. 1A and 1B, an active region ACT is disposed on a predetermined region of a semiconductor substrate 10. Word lines WL are disposed on the active region ACT. A source region 12S and a drain region 12D are disposed in the active region ACT in both sides of the word lines WL. A plug 16 and a pad 18 are stacked on the drain region 12D. An interlayer insulating layer 14 is disposed on the resultant structure with the pad 18. The interlayer insulating layer 14 has an opening part 20 exposing the top surface of the pad 18. A lower electrode 24 (which functions as a resistive heater) is disposed between a spacer 22 in the opening part 20, and a phase change pattern GST (contacting the lower electrode 24) and an upper electrode 28 are stacked on the interlayer insulating layer 14.

The electric resistance of a conductive line is proportional to its resistivity and length and inversely proportional to its sectional area. Accordingly, efforts to reduce the sectional area of the lower electrode 24 have been made in order to advantageously increase its electric resistance (for example, in FIG. 1B, the spacer 22 is formed in the opening part 20 to reduce the sectional area of the lower electrode 24).

However, any reduction in the sectional area of the upper region of the lower electrode 24 (i.e., the interface region with the phase change pattern GST which heats the phase change pattern GST) by means of the spacer 22 also reduces that of a lower region of the lower electrode 24 (i.e., a region of the lower electrode 24 which does not contribute to heating of the phase change pattern GST). Consequently, as illustrated in FIG. 1C, while the reduction in sectional area of the lower electrode 24 advantageously increases an interface resistance R4 between the phase change pattern GST and the lower electrode 24, it also increases a resistance R5 the lower electrode and an interface resistance R6 between the lower electrode and the diode. The increases in resistances R5 and R6 disadvantageously increase power consumption without substantially contributing to heating of the phase change pattern GST.

In the meantime, the opening part 20 is formed by a patterning process such as a photolithography process. Process deviations can cause variations in the opening part 20, which in turn can cause variations in the sectional area of the lower electrode 24. The result lack of cell uniformity can adversely impact PRAM yields, particularly the degree of integration increases.

Process yields can further deteriorate as a result of anisotropic etching processes utilization during formation of the phase change patterns GST islands of each cell. That is, etching damage can result which may affect physical characteristics of the phase change patterns GST, particularly in the case of an island shaped phase change pattern GST (such as those illustrated in FIG. 1A). Further, since a contact area between the island shaped phase change pattern GST and its under-layers (e.g., the lower electrode 24 and the interlayer insulating layer 14) is relatively small, a lifting problems resulting from thermal expansion can result.

### SUMMARY OF THE INVENTION

Embodiments of the present invention provide a semiconductor device which includes a lower electrode including a bottom wall portion and a sidewall portion extending upwardly from the bottom wall portion, an insulating layer located over a top edge surface of the sidewall portion of the lower electrode, the insulating layer including a contact window which partially exposes the top edge surface of the sidewall portion of the lower electrode, and a heated pattern which contacts the partially exposed top edge surface of the sidewall portion of the lower electrode through the contact window of the insulating layer.

In other embodiments of the present invention, a method of forming a semiconductor device includes forming an external insulating pattern with a gap region on a semiconductor substrate, forming a lower electrode with a bottom wall portion and a sidewall portion in the gap region, the sidewall portion extending upwardly from the bottom portion, forming an insulating layer with a contact window on the external insulating pattern, the contact window partially exposing the top edge surface of the sidewall portion of the lower electrode, and forming a heated pattern on the insulating layer which contacts the partially exposed top edge surface of the sidewall portion of the lower electrode through the contact window.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1A is a plan view of a conventional PRAM memory cell;

FIG. 1B is a cross-sectional view taken along line I-I′ of FIG. 1A;

FIG. 1C is a diagram illustrating resistive components of a conventional PRAM;

FIGS. 2A through 2C are plan views of a semiconductor device according to embodiments of the present invention;

FIGS. 3A through 3G are perspective views for use in describing a method of forming a semiconductor device according to an embodiment of the present invention;

FIG. 4 is a sectional view for use in describing a method of forming a semiconductor device according to another embodiment of the present invention;

FIGS. 5A and 5B are perspective views for use in describing a method of forming a semiconductor device according to another embodiment of the present invention;

FIGS. 6A and 6B are plan views of a semiconductor device according to another embodiment of the present invention;

FIGS. 7A through 7D are perspective views for use in describing a method of forming a semiconductor device according to further another embodiment of the present invention;

FIG. 8 is a perspective view of a semiconductor device according to another embodiment of the present invention; and

FIG. 9 is a perspective view for use in describing a method of forming a semiconductor device according to further another embodiment of the present invention.

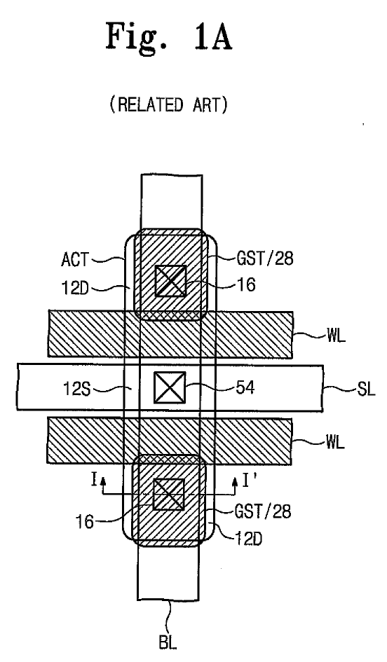

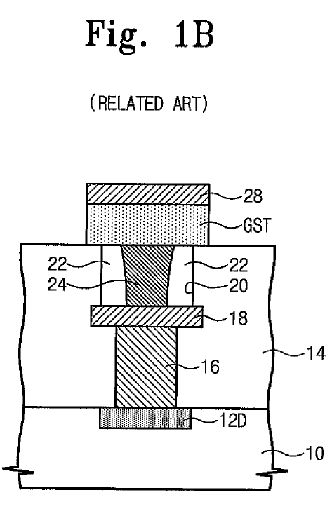

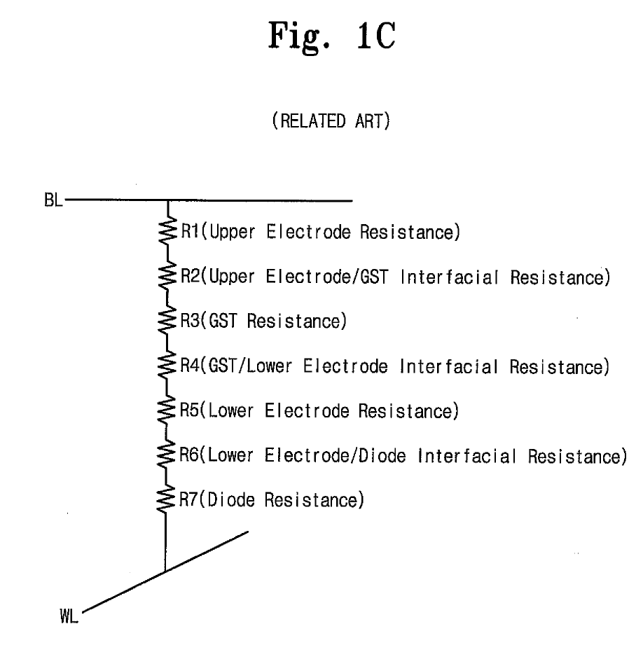

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

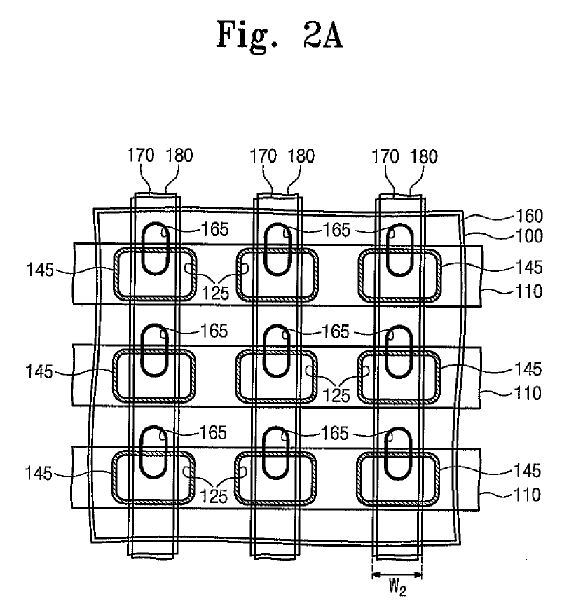

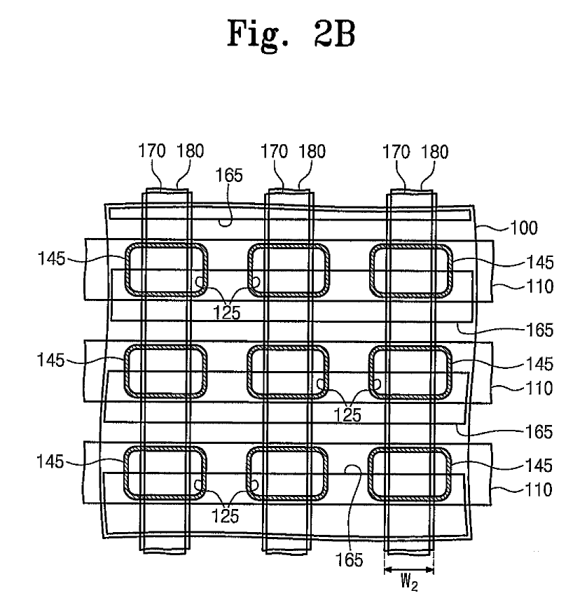

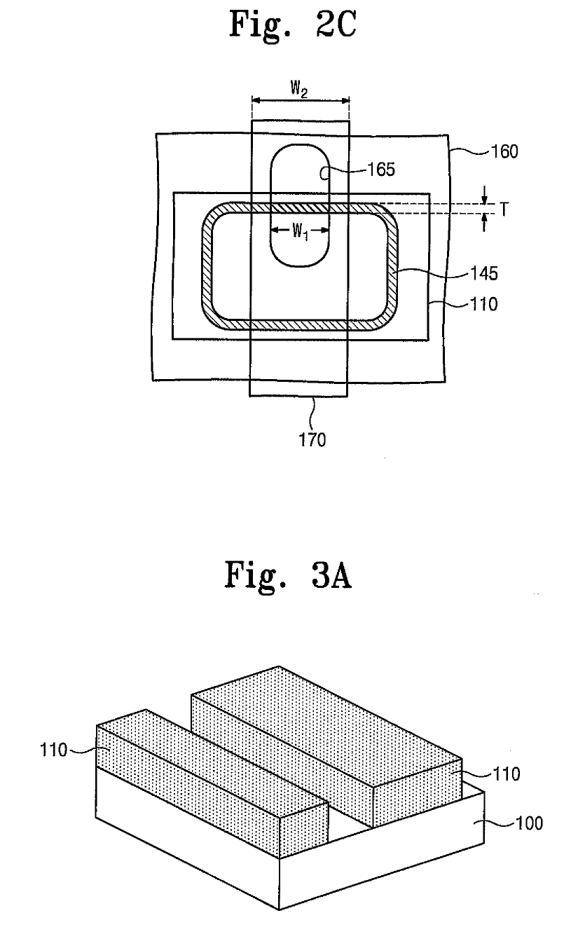

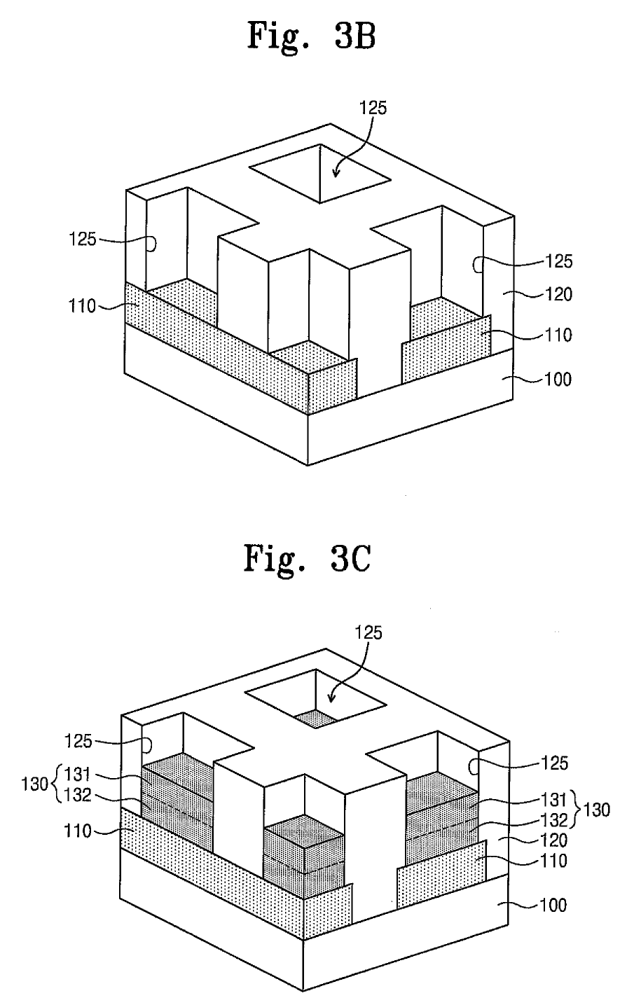

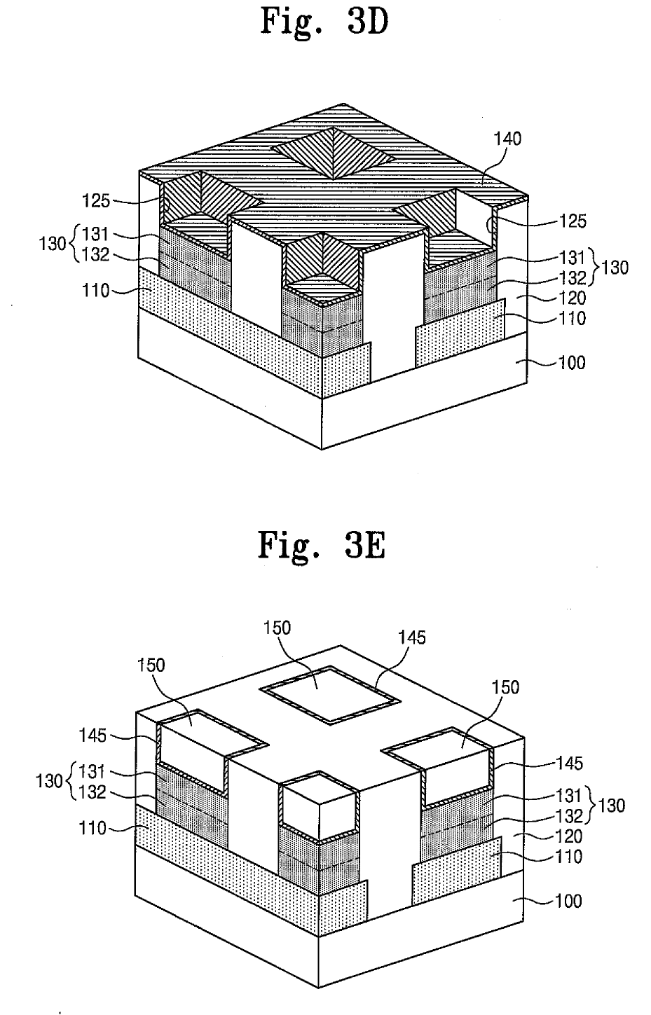

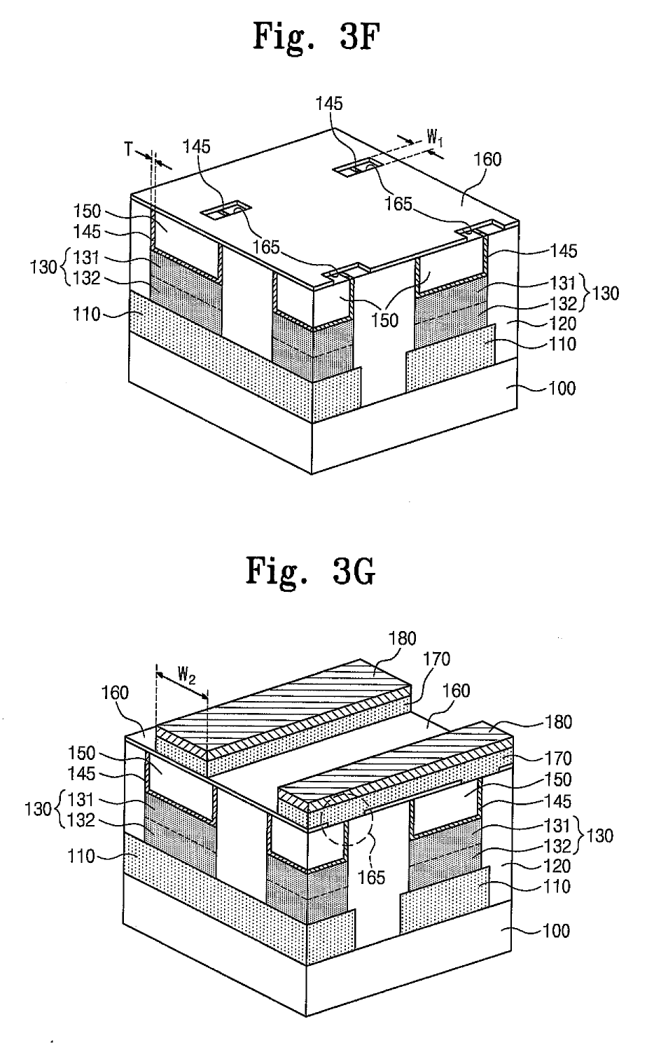

FIG. 2A is a plan view of a semiconductor device structure according to an embodiment of the present invention. FIGS. 3A through 3G are perspective views for describing a method of forming a semiconductor device according to one embodiment of the present invention. The semiconductor device includes a heating element, and in the example of this embodiment, is implemented in a PRAM.

Referring to FIGS. 2A and 3A, lower conductive patterns 110 are formed on (or in) a semiconductor substrate 100. The lower conductive pattern 110 may be used as an interconnecting line (more specifically, a word line) which connects memory cells of the PRAM in a predetermined direction.

For example, the lower conductive patterns may be formed by active regions in the substrate 100 using shallow trench isolation (STI). More specifically, device isolation trenches defining the active regions may be formed in the semiconductor substrate 100, and impurities may be implanted in the active regions to form highly-doped regions which function as the lower conductive pattern 110. Generally, the conductivity type of the impurities will be opposite that of the semiconductor substrate 100. For example, if the conductivity type of the semiconductor substrate is p-type, the lower conductive pattern 110 may be a highly doped n-type patterned region.

In another example, the lower conductive pattern 110 may formed by patterning of a metal material on the substrate 100. For example, methods disclosed in U.S. Patent Publication No. 2007/0111487, published May 17, 2007, may be referenced in this respect.

Referring to FIGS. 2A and 3B, a first insulating layer 120 is formed on the semiconductor substrate 100 to cover the lower conductive patterns 110. The first insulating layer 120 is used as an external insulating pattern that surrounds a lower electrode during the next process, and may, for example, be formed of at least one of a silicon oxide layer, a silicon nitride layer, a silicon oxynitride layer, and a low-k dielectric layer.

The first insulating layer 120 is patterned to form gap regions 125 that expose the top surface of the lower conductive patterns 110. The gap regions 125 may be formed by forming a first mask pattern (not shown) on the first insulating layer 120, and then using the first mask pattern as an etch mask to anisotropically etch the first insulating layer 120. The etching of the first insulating layer 120 may be performed by using an etch composition which exhibits etch selectivity relative to the lower conductive pattern 110.

The first mask pattern may be a photoresist pattern that is formed using a photolithography process. In this case, the corners of the gap regions 125 may be rounded. For example, the gap regions 125 may have an elliptical shape with a major axis and a minor axis in a direction parallel to a surface of the substrate 100. According to example of the present embodiment, the major axis of the gap region 125 is parallel to the length direction of the lower conductive pattern 110 to reduce a sidewall curvature of the gap region 125, which is measured at a direction that crosses over the lower conductive patterns 110. For example, the gap region 125 width along the major axis and/or the minor axis may be between 1 and 250 nm.

Moreover, as illustrated in FIGS. 2A and 3B, a plurality of gap regions 125 may be arranged to be spaced apart in a two-dimensional pattern, such a two-dimensional array. In this manner, a plurality of gap regions 125 may be formed on each lower conductive pattern 110.

Referring to FIGS. 2A and 3C, a semiconductor pattern 130 is formed in a lower region of the gap region 125. The semiconductor pattern 130 includes an upper impurity region 131 and a lower impurity region 132, which are sequentially stacked to constitute a diode. The lower impurity region 132 contacts the top surface of the lower conductive pattern 110. When the lower conductive pattern 110 is made of doped polycrystalline silicon, the lower impurity region 132 has a conductivity type which is the same as that of the lower conductive pattern 110, and the upper impurity region 131 has a conductivity type which is different from that of the lower conductive pattern 110.

According to the present invention, the forming of the semiconductor pattern 130 includes forming a semiconductor layer that fills the gap region 125, and etching back the semiconductor layer until the sidewall of the upper region in the gap region 125 is exposed. The height of the sidewall in the gap region 125 determines the height of a lower electrode (which will be formed in the next process). Therefore, the etching back of the semiconductor layer is performed in consideration thereof.

The semiconductor layer may be formed using an epitaxial process that utilizes the lower conductive pattern 110, which is exposed through the gap region 125, as a seed layer, and may be one of III, IV and V elements and the combination thereof. For example, the semiconductor layer may be one of an epitaxial Ge—Si layer and an epitaxial Si layer. As an example of one alternative, the semiconductor layer may be an amorphous Si layer that is formed using chemical vapor deposition (CVD).

The forming of the upper and lower impurity regions 131 and 132 includes performing ion implantation processes to implant impurities of respectively different conductive types in the semiconductor layer. According to another embodiment of the present invention, a first conductive type impurity is implanted in the semiconductor layer during an epitaxial process using an in-situ doping technique. Then, a second conductive type impurity is implanted in the semiconductor layer with the first conductive type impurity by using an ion implantation technique.

Referring to FIGS. 2A and 3D, lower electrode layer 140 is formed on the resultant structure having the semiconductor pattern 130. That is, the lower electrode layer 140 covers the top surface of the first insulating layer 120 and an inner wall of the gap region 125. That is, the lower electrode layer 140 covers the sidewall exposed at the upper region of the gap region 125 and the top surface of the semiconductor pattern 130.

According to the present invention, as will be explained below, the thickness of the lower electrode layer 140 determines the contact area between the lower electrode and the heated pattern. Therefore, the lower electrode layer 140 is preferably formed using a method capable of precisely controlling the thickness thereof. For example, the lower electrode layer 140 may be formed using one of atomic layer deposition (ALD), metal organic chemical vapor deposition (MO-CVD), Thermal CVD, Biased CVD, Plasma CVD and ECR CVD. According to this embodiment, the thickness of the lower electrode layer 140 may, for example, be between 1 and 30 nm.

Additionally, the lower electrode layer 140 may be formed using at least one selected from the group consisting of nitrides including metal atoms, oxynitrides including metal atoms, C, Ti, Ta, TiAl, Zr, Hf, Mo, Al, Al—Cu, Al—Cu—Si, Cu, W, TiW, and WSix. Here, the nitrides with metal atoms include TiN, TaN, WN, MoN, NbN, TiSiN, TiAlN, TiBN, ZrSiN, WSiN, WBN, ZrAlN, MoSiN, MoAlN, TaSiN, and TaAlN. The oxynitrides with metal atoms include TiON, TiAlON, WON, and TaON. According to this embodiment, the lower electrode layer 140 is formed of a titanium nitride layer.

Referring to FIGS. 2A and 3E, a second insulating layer is formed on the resultant structure with the lower electrode layer 140 to fill the upper portion of the gap region 125. Then, the second insulating layer and the lower electrode layer 140 are planarized by an etching process in order to expose the top surface of the first insulating layer 120. Consequently, as illustrated in FIG. 3E, a lower electrode 145 having the bottom portion and sidewall portion, and an inner insulating pattern 150 disposed on the bottom portion are formed in the upper portion of the gap region 125.

The second insulating layer may be one of a silicon oxide layer and a silicon nitride layer, and may be formed using CVD. Additionally, an etching process for planarization may be performed using chemical mechanical polishing (CMP) techniques.

The bottom portion is formed to contact with the top surface of the semiconductor pattern 130 and has the same area as the gap region 125. The sidewall portion extends upwardly from the bottom portion to the entrance of the gap region 125. The lower electrode 145 forms a closed line, in that it is formed by planarizing the lower electrode that conformally covers the gap region 125. More specifically, the sidewall portion may be formed to have a sectional area of a ring shape. The top surface of the sidewall portion of the lower electrode 145 is exposed at the entrance of the gap region 125.

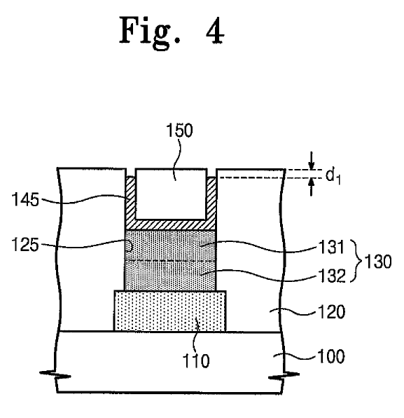

Meanwhile, according to one embodiment, as illustrated in FIG. 4, etching of the lower electrode 145 may be further performed, such that the top surface of the sidewall portion of the lower electrode 145 is lower than the top surface of the first insulating layer 120. In this case, since sidewalls of the sidewall portion of the lower electrode 145 are not exposed, the contact area between the lower electrode 145 and the phase change layer (which will be formed on the lower electrode 145) and a variation of the contact area can be minimized. That is, since only the top surface of the sidewall portion of the lower electrode 145 is exposed, the contact area can be stably controlled.

Referring to FIGS. 2A and 3F, an insulating layer 160 is formed on the resultant structure with the lower electrode 145, and then is patterned to form a contact windows 165 exposing a portion of the top surface of the sidewall portion.

The insulating layer 160 may, for example, be formed of a material with resistivity of 10×10⁻³ Ωcm, low heat-conductivity, and excellent adhesive property with respect to the heated pattern 170, which will be formed in a subsequent process. For example, the insulating layer 160 may be formed of one selected from the group consisting an AlN, SiN, SiON, SiO₂, amorphous carbon, TiO₂, Ta₂O₅, AlOₓ, HfOₓ, LaOₓ, and Y₂Oₓ, and may have a thickness of 5 to 1000 Å.

The contact window 165 is formed to expose a portion of the sidewall portion of the lower electrode 145. More specifically, the contact window 165 is formed with a narrower width W₁ than the bottom portion of the lower electrode 145. The center point of the contact window 165 is located on the edge of the gap region 125, i.e., it is not aligned with the central axis of the gap region 125. According to one embodiment of the present invention, the contact windows 165 may be respectively formed on each of the lower electrodes 125. For example, the contact window 165 may have a width of 5 Å to 1000 Å and an aspect ratio of 0.0001 to 2.

The contact windows 165 may be formed using a photolithography process. In this case, the corners of the contact windows 165 may be rounded. For example, the contact window 165 may be an oval having a major axis and a minor axis in a direction parallel to a surface of the substrate 100. According to one embodiment of the present invention, the major axis of the contact window 165 may be perpendicular to the length direction of the lower conductive pattern 110 to reduce a sidewall curvature of the contact window 165, which is measured in a direction parallel to the lower conductive patterns 110. The major axis length or the minor axis length of the contact window 165 may be between 1 and 100 nm.

Referring to FIGS. 2A and 3G, the heated pattern 170 and the upper electrode 180 crossing over the lower conductive patterns 110 are sequentially stacked over the contact windows 165. The heated pattern 170 and the upper electrode 180 contact the lower electrode 145 through the contact window 165.

In the example of a PRAM, the heated pattern 170 may be formed of a chalcogen compounds including at least one of Sb, Te, and Se. For example, the heated pattern 170 may be Ge₂₂Sb₂₂Te₅₆. In one composition providing an improved electrical switching characteristic, a concentration of Te may be between 20 and 80 atomic percent, and a concentration of Sb may be between 5 and 50 atomic percent, the rest of them may be Ge. Additionally, the heated pattern 170 may be formed of a GeSbTe layer including at least one impurity selected from the group consisting N, O, C, Bi, In, B, Sn, Si, Ti, Al, Ni, Fe, Dy and La, or may be formed of one selected from the group consisting GeBiTe, InSb, GeSb, and GaSb.

The upper electrode 180 may be formed using at least one selected from the group consisting nitrides with metal atoms, oxynitrides with metal atoms, C, Ti, Ta, TiAl, Zr, Hf, Mo, Al, Al—Cu, Al—Cu—Si, Cu, W, TiW, and WSix. At this point, the nitrides with metal atoms include TiN, TaN, WN, MoN, NbN, TiSiN, TiAlN, TiBN, ZrSiN, WSiN, WBN, ZrAlN, MoSiN, MoAlN, TaSiN, and TaAlN. The oxynitrides with metal atoms include TiON, TiAlON, WON, and TaON. According to this embodiment, the upper electrode 180 is formed of a titanium nitride layer. Bit lines (not shown) crossing over the lower conductive pattern 110 (used as word lines) may be disposed on the upper electrode 180.

According to this embodiment, as illustrated in FIG. 2C, the width W₂ of the heated pattern 170 is formed broader than the width W₁ of the contact window 165 such that the heated pattern 170 completely covers the contact window 165. In this case, the contact area where the lower electrode 145 contacts the heated pattern 170 is a product of the thickness T of the sidewall portion of the lower electrode 145 and the width W₁ of the contact window 165. As described above, if the contact window 165 and the gap region 125 are rounded by a photolithography process, the contact area may be different from T×W due to their sidewall curvatures.

Meanwhile, the thickness T of the sidewall portion is determined by the thickness of the lower electrode layer 140, and the lower electrode layer 140 is preferably formed using deposition methods that accurately control its thickness in the order of angstroms. Accordingly, the thickness of the sidewall portion and its variation are much smaller when compared to those of a plug-type lower electrode, which is formed using a conventional photolithography process. Consequently, the contact area between the lower electrode 145 and the heated pattern 170 becomes smaller when compared to that of a conventional plug-type lower electrode. Furthermore, since the variation of the contact area between the lower electrode 145 and the heated pattern 170 is one-dimensionally determined by the distribution of the width W₁ of the contact window 165, it is much smaller than that of the conventional technique (which may be two-dimensionally varied). That is, according to the present embodiment, both the contact area between the lower electrode 145 and the heated pattern 170 and its variation can be simultaneously reduced.

According to the present embodiment, even if the contact area between the lower electrode 145 and the heated pattern 170 is reduced, the contact area between the lower electrode 145 and its under-layer (for example, the semiconductor pattern 130) is identical to the sectional area of the gap region 125. Further, although the sidewall portion of the lower electrode 145 contacts the heated pattern 170, the sidewall portion of the lower electrode 145 is used as an interconnection line for connecting the semiconductor pattern 130 with the heated pattern 170. Consequently, although the interfacial resistance between the lower electrode 145 and the heated pattern 170 are significantly increased, a bulk resistance of the lower electrode 145 or the interfacial resistance between the lower electrode 145 and the semiconductor pattern 130 are not significantly increased.

Furthermore, according to the present embodiment, the heated pattern 170 is patterned concurrently with the upper electrode 180, and thus is aligned with the upper electrode 180. Accordingly, the heated pattern 170 is formed to cross over a plurality of memory cells (that is, the lower electrodes 145). As a result, it is possible to reduce problems associated with the deterioration of product characteristics caused by an etching damage or lifting of the phase change patterns, which occur in the conventional island-shape phase change patterns.

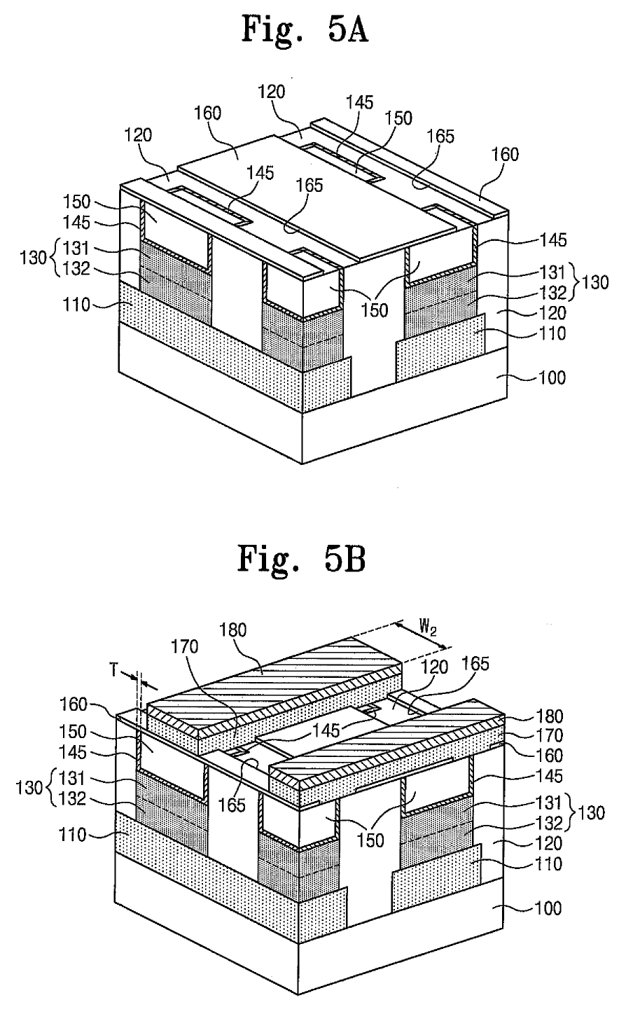

FIG. 2B is a plan view of a semiconductor device having a heating structure according to another embodiment of the present invention. FIGS. 5A and 5B are perspective views for use in describing a method of forming a semiconductor device having a heating structure according to another embodiment of the present invention. This embodiment is similar to the embodiment described above in connection with FIG. 2A, except for technical differences related to the contact window 165. Accordingly, the description below is abbreviated to avoid redundancy.

Referring to FIGS. 2B and 5A, after forming the insulating layer 160, the insulating layer 160 is patterned to form the contact window that exposes a portion of the top surface of the sidewall portion of the lower electrode 145. According to this embodiment, the contact window 165 is formed in a direction parallel to the lower conductive pattern 145, and one contact window 165 exposes a plurality of lower electrodes 145. That is, unlike the embodiment of FIG. 2A, the contact window 165 is formed in a line shape.

Referring to FIGS. 2B and 5B, the heated pattern 170 and the upper electrode 180 crossing over the lower conductive patterns 110 are sequentially stacked over the contact window 165. The heated pattern 170 and the upper electrode 180 contact the lower electrodes 145 through the contact window 165. According to this embodiment, since the contact window 165 is formed in a line, the contact area between the lower electrode 145 and the heated pattern 170 is a product of the width W₂ of the heated pattern 170 and the thickness T of the sidewall portion of the lower electrode 145. At this point, the width of the heated pattern 170 is smaller than the width of the gap region 125 (that is, the width of the bottom portion of the lower electrode 145) in order to minimize the contact area. Consequently, a portion of the top surface of the lower electrode may be exposed through the contact window 165 in both sides of the heated pattern 170.

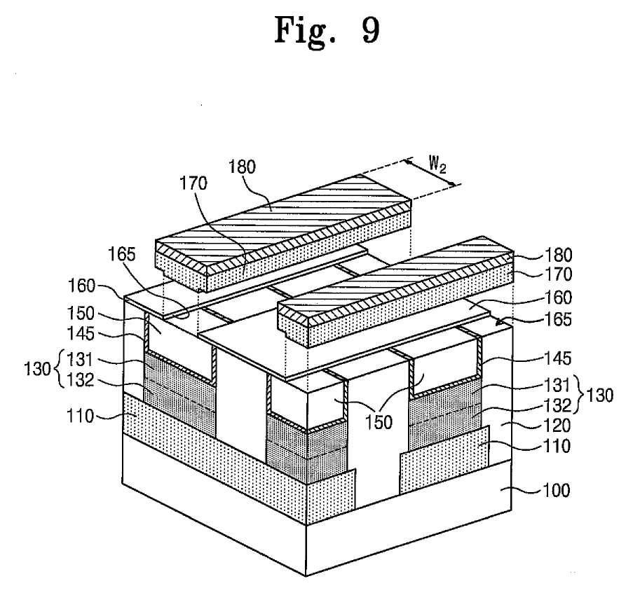

Meanwhile, according to another embodiment of the present invention, the contact window 165, as illustrated in FIG. 9, may be formed in a direction crossing over the lower conductive patterns 145. In this case, each contact window 165 is formed to have a line shape, and it exposes the top surfaces of the lower electrodes 145. Additionally, according to this embodiment, the contact window 165 may be formed smaller than the width of the heated pattern 170. In this case, the contact area between the heated pattern 170 and the lower electrode 145 is a product of the thickness of the sidewall portion and the width of the contact window 165.

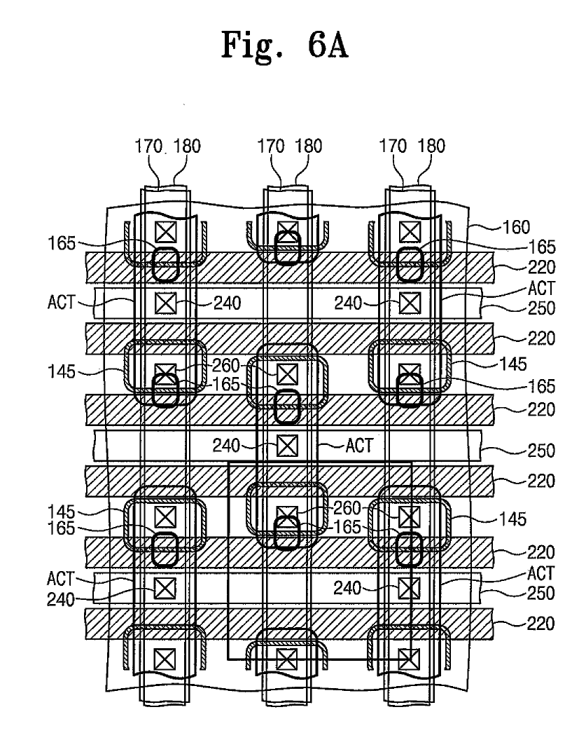

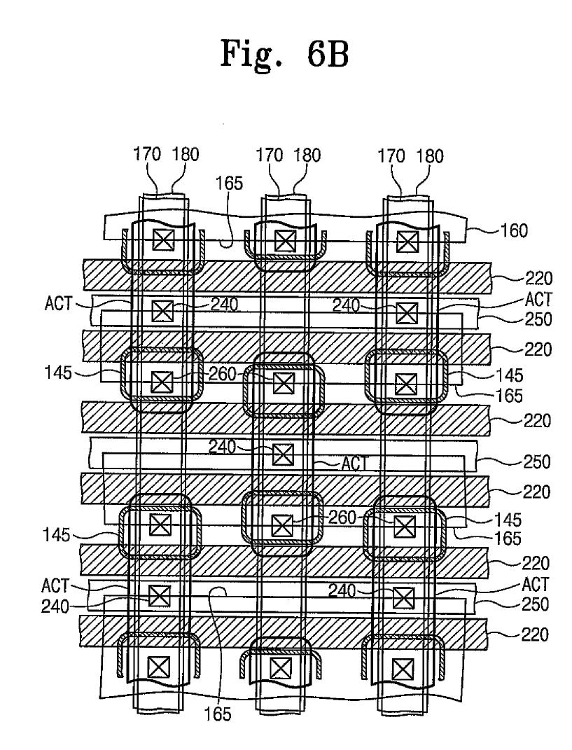

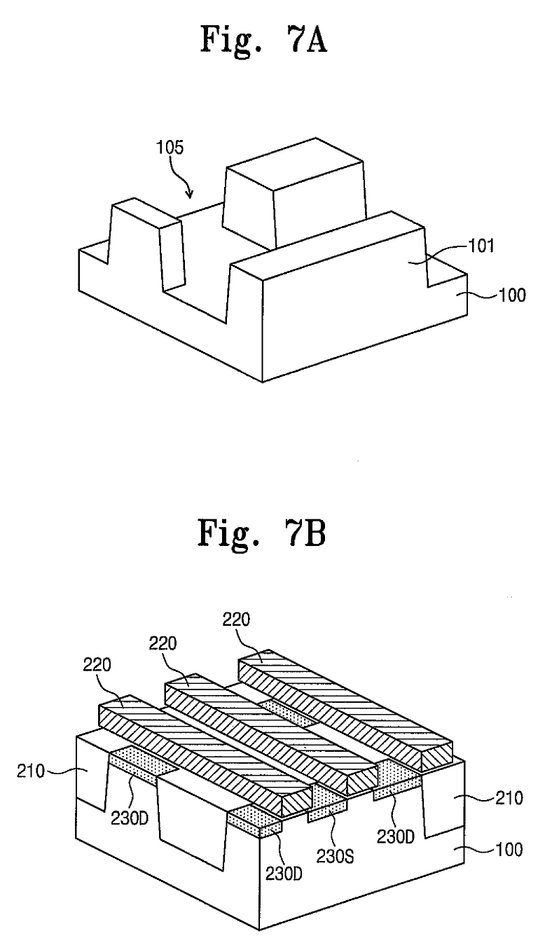

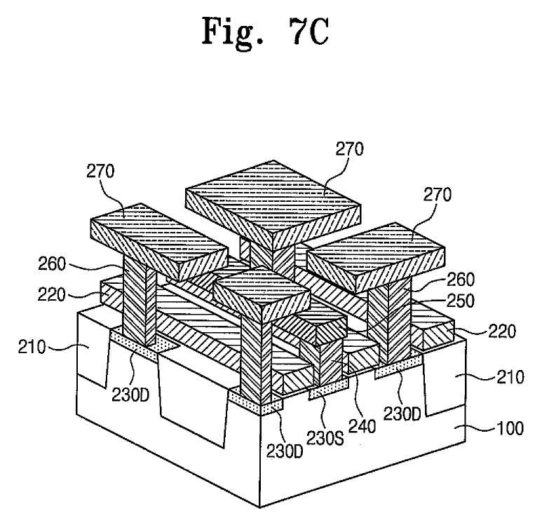

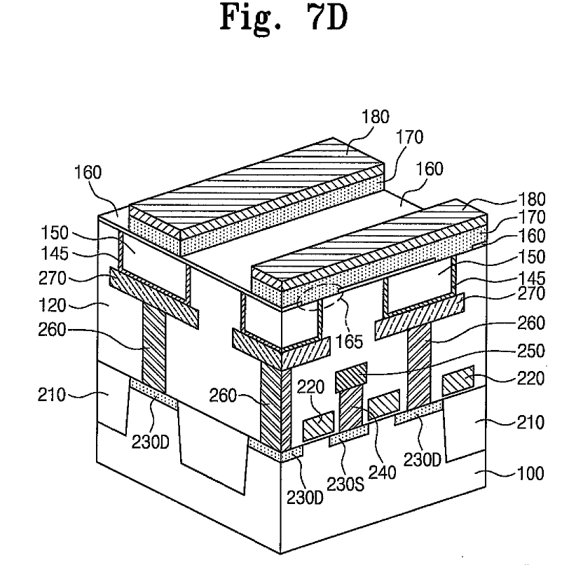

FIG. 6A is a plan view of a semiconductor device having a heating structure according to another embodiment of the present invention. FIGS. 7A through 7D are perspective views for use in describing a method of forming a semiconductor device having a heating structure according to another embodiment of the present invention. This embodiment is similar to the embodiment described referring to FIG. 2A, except that a current flow between the word line and the bit line is controlled by a transistor instead of a diode. Accordingly, the description below is abbreviated to avoid redundancy.

Referring to FIGS. 6A and 7A, trenches 105 are formed in a predetermined region of a semiconductor substrate 100 to define active regions 101. The trenches 105 may be formed using a well-known shallow trench isolation (STI) technique. According to one embodiment of the present invention, the active regions 101 may be disposed in a structure similar to that of DRAM.

Referring to FIGS. 6A and 7B, device isolation layer patterns 210 are formed to fill the trenches, and gate patterns 220 are formed to cross over the active regions 101. The gate patterns 220 (used as word lines) constitute gate electrodes of memory cell transistors. Before the forming of the gate patterns 220, a gate insulating layer (not shown) may be further formed on the top surfaces of the active regions 101.

Next, impurity regions defining a source region 230S and a drain region 230D are formed in the active regions 101 in both sides of the gate patterns 220 by performing an ion implantation process that utilizes the gate patterns 220 as a mask. According to the present embodiment, a pair of the gate patterns 220 is formed crossing over one active region 101. Consequently, a pair of drain regions 230D are formed in the active region 101 outside the pair of the gate patterns 220, and the source region 230S is formed in the active region 101 between the gate patterns 220.

Referring to FIGS. 6A and 7C, a source plug 240 and a source line 250 are formed to contact the source region 230S. The source line 250 is parallel to the gate patterns 220, and the source plug 240 electrically connects the source line 250 with the source region 230S. Next, a drain plug 260 is formed to be connected to the drain regions 230D, and pads 270 are formed to be connected to the drain plug 260.

Referring to FIGS. 6A and 7D, a first insulating layer 120 is formed on the resultant structure, and the first insulating layer 120 is formed to define the gap regions 125 that expose the top surface of the pad 270. Next, the lower electrode 145 and the inner insulating pattern 150 are formed in the gap region 125, and an insulating layer 160 having the contact window 165 is formed on the resultant structure. Next, the heated pattern 170 and the upper electrode 180 connecting to the lower electrode 145 through the contact window 165 are sequentially formed. Remaining processes are similar to those of the embodiment described previously in connection with FIGS. 3D through 3G.

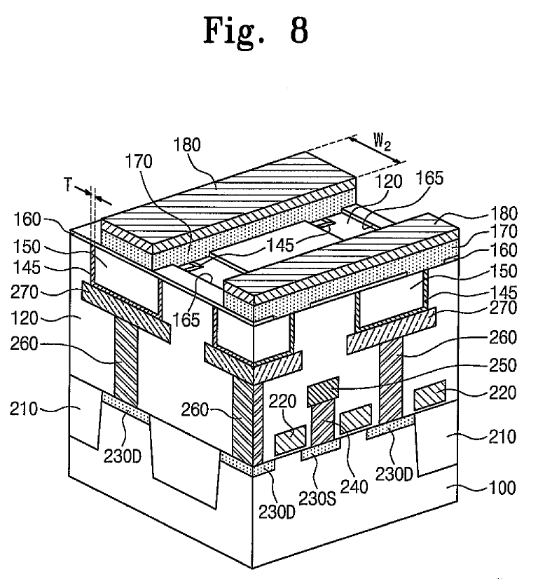

FIG. 6B is a plan view of a semiconductor device having a heating structure according to another embodiment of the present invention. FIG. 8 is a perspective view of a semiconductor device having a heating structure according to another embodiment of the present invention. This embodiment is similar to the embodiment described referring to FIGS. 7A through 7B, except for technical differences related to the contact window 165. The description below is abbreviated to avoid redundancy.

Referring to FIGS. 6B and 8, after forming the insulating layer 160, the insulating layer 160 is patterned to form a contact window 165 that exposes a portion of the top surface of the sidewall portion of the lower electrode 145. According to this embodiment, the contact window 165 is formed in a direction parallel to the lower conductive pattern 145, and one contact window 165 exposes a plurality of lower electrodes 145. That is, unlike the embodiment of FIG. 2A, the contact window 165 is formed to have a line shape.

Next, a heated pattern 170 and an upper electrode 180 are formed to contact with the lower electrode 145 through the contact window 165. The forming steps of the heated pattern 170 and the lower electrode 145 may be the same as that of the embodiment described in connection with FIG. 7D.

According to embodiments described above, the heated pattern (e.g. a phase change pattern of PRAM) is connected to a portion of the sidewall portion of the lower electrode exposed through the contact window. In this case, the contact area of the phase change pattern and the lower electrode is a product the thickness of the sidewall portion and the width of the contact window. Since the lower electrode may be formed using deposition methods capable of accurately controlling a thickness of layer in the order of angstroms, both the contact area and its variation can be reduced. The reduction of the contact area improves electrical characteristics of the device, and the reduction of the variation of the contact area improves the uniformity of the memory cells.

Further, according to embodiments described above, the lower electrode may be formed without reducing a contact area with its under-layer. Accordingly, the interfacial resistance between the lower electrode and the phase change pattern can be selectively increased, and this selective increase of interfacial resistance serves to improve the electrical characteristics of the semiconductor device.

Additionally, according to embodiments described above, the heated pattern may be patterned in a line-shape that crosses over a plurality of memory cells (that is, lower electrodes). Therefore, problems such as the deterioration of the product characteristics caused by an etching damage or the lifting of the phase change patterns can be reduced relative to conventional island-shape phase change patterns.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor device comprising:
a lower electrode including a bottom wall portion and a sidewall portion extending upwardly from the bottom wall portion;
an insulating layer located over a top edge surface of the sidewall portion of the lower electrode, the insulating layer including a contact window which partially exposes the top edge surface of the sidewall portion of the lower electrode; and
a heated pattern which contacts the partially exposed top edge surface of the sidewall portion of the lower electrode through the contact window of the insulating layer.

2. The semiconductor device of claim 1, wherein a width of the contact window is less than a width of the heated pattern; and
wherein a contact area between the heated pattern and the lower electrode is a product of a thickness of the sidewall portion and the width of the contact window.

3. The semiconductor device of claim 1, wherein the partially exposed top edge surface of the sidewall portion of the lower electrode extends in a direction which is perpendicular to a lengthwise direction of the heated pattern; and
wherein a contact area between the heated pattern and the lower electrode is a product of a thickness of the sidewall portion and a width of the heated pattern.

4. The semiconductor device of claim 1, wherein the partially exposed top edge surface of the sidewall portion of the lower electrode extends in a direction which is parallel to a lengthwise direction of the heated pattern; and
wherein a contact area between the heated pattern and the lower electrode is a product of a thickness of the sidewall portion and a width of the contact window.

5. The semiconductor device of claim 1, wherein the lower electrode is one of a plurality of lower electrodes each including a bottom wall portion and a sidewall portion extending upwardly from the bottom wall portion;
wherein an insulating layer includes a plurality of contact windows which partially expose the top edge surface of the sidewall portion of the plurality of lower electrodes, respectively; and
wherein the heated pattern contacts the plurality of lower electrodes through the plurality of contact windows, respectively.

6. The semiconductor device of claim 1, wherein the heated pattern is formed of a material including at least one of Sb, Te, and Se.

7. The semiconductor device of claim 1, wherein the lower electrode is formed of at least one selected from the group consisting nitrides with metal atoms, oxynitrides with metal atoms, C, Ti, Ta, TiAl, Zr, Hf, Mo, Al, Al—Cu, Al—Cu—Si, Cu, W, TiW, and WSix,
wherein the nitrides with metal atoms comprises TiN, TaN, WN, MoN, NbN, TiSiN, TiAlN, TiBN, ZrSiN, WSiN, WBN, ZrAlN, MoSiN, MoAlN, TaSiN, and TaAlN,
wherein the oxynitrides with metal atoms comprises TiON, TiAlON, WON, and TaON.

8. The semiconductor device of claim 1, wherein the sidewall portion of the lower electrode is a closed line having a thickness of 1 to 20 nm.

9. The semiconductor device of claim 1, further comprising a upper electrode disposed on and aligned with the heated pattern.

10. The semiconductor device of claim 9, wherein the upper electrode is formed of at least one selected from the group consisting nitrides with metal atoms, oxynitrides with metal atoms, C, Ti, Ta, TiAl, Zr, Hf, Mo, Al, Al—Cu, Al—Cu—Si, Cu, W, TiW, and WSix,
wherein the nitrides with metal atoms comprises TiN, TaN, WN, MoN, NbN, TiSiN, TiAlN, TiBN, ZrSiN, WSiN, WBN, ZrAlN, MoSiN, MoAlN, TaSiN, and TaAlN,
wherein the oxynitrides with metal atoms comprises TiON, TiAlON, WON, and TaON.

11. The semiconductor device of claim 1, further comprising:
a lower conductive pattern disposed below the lower electrode and extending lengthwise in a direction perpendicular to the heated pattern; and
a semiconductor diode interposed between the lower conductive pattern and the lower electrode.

12. The semiconductor device of claim 11, wherein the lower electrode and the semiconductor diode are aligned with each other.

13. The semiconductor device of claim 11, wherein the lower conductive pattern comprises at least one of polycrystalline silicon, silicides, and metals.

14. The semiconductor device of claim 5, further comprising:
a plurality of inner insulating patterns interposed between the bottom portion of the respective lower electrodes and the insulating layer; and
an external insulating pattern which electrically isolates the lower electrodes from each other,
wherein the partially exposed top edge surface of the sidewall portion of each lower electrode is lower than top surfaces of the inner insulating patterns and the external insulating pattern.

15. The semiconductor device of claim 1, further comprising:
a transistor disposed below the lower electrode and comprising a gate electrode extending lengthwise in a direction perpendicular to the heated pattern, and source/drain regions formed at opposite sides of the gate electrode.

16. The semiconductor device of claim 15, further comprising:
a source line extending lengthwise in a direction parallel to the gate electrode;
a source plug which connects the source region with the source line; and
a drain plug which connects the drain region with the lower electrode.

17. The semiconductor device of claim 1, wherein the insulating layer has a thickness of 20 to 200 Å, and is formed of one of a material having a resistivity of at least 10×10⁻³ Ωcm.

18. The semiconductor device of claim 1, wherein the contact window has a depth of 5 to 1000 Å, and has an aspect ratio of 0.0001 to 2.

19. A method of forming a semiconductor device, the method comprising:
forming an external insulating pattern with a gap region on a semiconductor substrate;
forming a lower electrode with a bottom wall portion and a sidewall portion in the gap region, the sidewall portion extending upwardly from the bottom portion;
forming an insulating layer with a contact window on the external insulating pattern, the contact window partially exposing the top edge surface of the sidewall portion of the lower electrode; and
forming a heated pattern on the insulating layer which contacts the partially exposed top edge surface of the sidewall portion of the lower electrode through the contact window.

20. The method of claim 19, further comprising, before the forming of the lower electrode, forming a semiconductor diode disposed in a lower portion of the gap region, wherein the lower electrode is formed over the semiconductor diode.

21. The method of claim 20, further comprising, before the forming of the external insulating pattern, forming a lower conductive pattern in or over the substrate, wherein the semiconductor diode is formed on the lower conductive pattern, and wherein a lengthwise direction of the heated pattern is perpendicular to a lengthwise direction of the lower conductive pattern.

22. The method of claim of 21, wherein the forming of the semiconductor diode comprising:
performing an epitaxial process to form a semiconductor layer filling the gap region, the epitaxial process using the lower conductive pattern as a seed layer;
etching back the semiconductor layer to form a semiconductor pattern exposing an upper sidewall of the gap region; and
sequentially implanting impurities of different conductivity types into the semiconductor layer to form the diode.

23. The method of claim 19, further comprising, before the forming of the external insulating pattern:
forming a transistor which includes a gate electrode extending perpendicular to the heated pattern and source/drain regions on opposite sides of the gate electrode; and
forming a drain plug which electrically connects the drain region of the transistor with the lower electrode.

24. The method of claim 19, further comprising, before the forming of the insulating layer, forming an inner insulating pattern on the bottom portion of the lower electrode to at least partially fill the gap region.

25. The method of claim 24, wherein the forming of the lower electrode and the inner insulating pattern comprises:
forming the lower electrode layer so as to cover the bottom wall and sidewall surfaces of the gap region;
forming an inner insulating layer on the lower electrode layer to fill the gap region; and
etching the inner insulating layer and the lower electrode layer to expose a top surface of the external insulating pattern.

26. The method of claim 25, wherein the lower electrode layer is formed using one of ALD (atomic layer deposition), MO-CV) (metal organic chemical vapor deposition), Thermal CVD, Biased CVD, Plasma CVD and ECR CVD.

27. The method of claim 25, wherein the lower electrode layer is formed to cover conformally the bottom and sidewall surfaces of the gap region with a thickness of 1 to 20 nm.

28. The method of claim 19, wherein the external insulating pattern is formed with a plurality of gap regions, and wherein a plurality of lower electrodes each including a bottom wall portion and a sidewall portion are formed in the respective gap regions, and wherein forming of the insulating layer comprises:
forming a layer of insulating material over the lower electrodes; and
patterning the layer of insulating material to form a plurality of contact windows which partially expose the top edge surface of the sidewall portion the plurality of lower electrodes, respectively.

29. The method of claim 19, wherein the external insulating pattern is formed with a plurality of gap regions, and wherein a plurality of lower electrodes each including a bottom wall portion and a sidewall portion are formed in the respective gap regions, and wherein forming of the insulating layer comprises:
forming a layer of insulating material over the lower electrodes; and
patterning the layer of insulating material to form a contact window which extends lengthwise in a direction perpendicular to the heated pattern and which partially exposes the top edge surface of the sidewall portion the plurality of lower electrodes.

30. The method of claim 19, wherein the forming of the insulating layer comprises:
forming the insulating layer over the lower electrode; and
patterning the insulating layer to form the contact window, wherein the contact window is formed to a depth of 5 to 100 Å and an aspect ratio of 0.0001 to 2.

31. The method of claim 19, wherein the forming of the heated pattern comprises:
forming a phase change layer on the insulating layer, the phase change layer contacting the partially exposed top edge surface of the sidewall portion of the lower electrode through the contact window; and
patterning the phase change layer to forming the heated pattern.

32. The method of claim 19, wherein the insulating layer is formed to a thickness of 20 to 200 Å and is formed of a material having a resistivity of at least 10×10⁻³ Ωcm;
wherein the lower electrode is formed of at least one selected from the group consisting TiN, TaN, WN, MoN, NbN, TiSiN, TiAlN, TiBN, ZrSiN, WSiN, WBN, ZrAlN, MoSiN, MoAlN, TaSiN, TaAlN, TiON, TiAlON, WON, TaON, C, Ti, Ta, TiAl, Zr, Hf, Mo, Al, Al—Cu, Al—Cu—Si, Cu, W, TiW, and WSix; and
wherein the heated pattern is formed of a material including at least one of Sb, Te, and Se.
